(19) United States
(12) Patent Application Publication
(10) Pub. No.: US 2025/0067603 A1
(43) Pub. Date: Feb. 27, 2025

(54) THERMOELECTRIC CONVERSION ELEMENT AND SENSOR MODULE

(71) Applicant: NITTO DENKO CORPORATION, Osaka (JP)

(72) Inventor: Kazuaki SUZUKI, Osaka (JP)

(73) Assignee: NITTO DENKO CORPORATION, Osaka (JP)

(21) Appl. No.: 18/724,527

(22) PCT Filed: Dec. 20, 2022
(86) PCT No.: PCT/JP2022/046827

§ 371 Date: Jun. 26, 2024

(30) Foreign Application Priority Data
Dec. 28, 2021 (JP) 2021-214740

(51) Int. Cl. G01K 7/00; H10N 10/17; H10N 10/856

(52) U.S. Cl. CPC G01K 7/00; H10N 10/17; H10N 10/856

(57) ABSTRACT

A thermoelectric conversion element includes a heat insulating material and a thermoelectric conversion member. A main body portion of the thermoelectric conversion member is disposed inside the heat insulating material and has a predetermined length in a thickness direction of the heat insulating material. A sensor module includes a heat insulating material, a first thermoelectric conversion member same as the thermoelectric conversion member, a conversion circuit converting electromotive force of the first thermoelectric conversion member into a signal, and a wireless module capable of transmitting the signal based on the electromotive force of the first thermoelectric conversion member converted by the conversion circuit.

### TECHNICAL FIELD

The present invention relates to a thermoelectric conversion element and a sensor module.

### BACKGROUND ART

Conventionally, it has been desired to install a sensor for detecting an abnormality, but there is a place where a power source for the sensor is difficult to be ensured.

Examples of the place include the interior of a heat insulating structure around piping used in industrial plants or the like.

As the heat insulating structure, for example, a piping cover structure having a dew-proof member disposed around cooling system piping of a nuclear power plant, and having a fire resistant metal board disposed around the dew-proof member and covering the dew-proof member has been known (ref: Patent Document 1 below).

### CITATION LIST

### Patent Document

Patent Document 1: Japanese Unexamined Patent Publication No. 2015-175506

### SUMMARY OF THE INVENTION

### Problem to be Solved by the Invention

In the piping cover structure as described in the above-described Patent Document 1, since the piping is covered with the dew-proof member and the fire resistant metal board, it is difficult to inspect the abnormality of the piping such as corrosion. The corrosion of the piping is, for example, caused by contact of rain water or the like which enters the inside of the piping cover structure with a piping surface.

Therefore, though it is desired to install the sensor for detecting the abnormality such as entry of the rain water into the piping cover structure inside the piping cover structure, the power source is difficult to be ensured.

The present invention provides a thermoelectric conversion element which is available as a sensor or a power source in a place where the power source is difficult to be ensured, and a sensor module which is installable in the place where the power source is difficult to be ensured.

### Means for Solving the Problem

The present invention [1] includes a thermoelectric conversion element including a heat insulating material having a predetermined thickness; and a thermoelectric conversion member having a thread-shape having a diameter of 150 m or more, having a portion disposed inside the heat insulating material and having a predetermined length in a thickness direction of the heat insulating material, and generating electromotive force due to a temperature difference in the thickness direction of the heat insulating material.

According to such a configuration, the heat insulating material having the predetermined thickness, and the thermoelectric conversion member are provided.

It is possible to ensure the temperature difference in the thickness direction of the heat insulating material by the heat insulating material.

The thermoelectric conversion member has the thread-shape having the diameter of 150 m or more, and has the portion disposed inside the heat insulating material. The portion disposed inside the heat insulating material has the predetermined length in the thickness direction.

Therefore, the thermoelectric conversion member can generate the large electromotive force by utilizing the temperature difference ensured by the heat insulating material. In particular, since the diameter of the thermoelectric conversion member is 150 m or more, it is possible to increase the electromotive force.

Therefore, the thermoelectric conversion element is available as the sensor or the power source in a place where the power source is difficult to be ensured.

The present invention [2] includes the thermoelectric conversion element of the above-described [1], wherein the heat insulating material includes at least one of glass wool, rock wool, and calcium silicate.

The present invention [3] includes the thermoelectric conversion element of the above-described [1] or [2], wherein the thermoelectric conversion member includes a carbon nanotube and a binder binding the carbon nanotube.

The present invention [4] includes the thermoelectric conversion element of the above-described [3], wherein the thermoelectric conversion member further includes a dopant.

The present invention [5] includes the thermoelectric conversion element of any one of the above-described [1] to [4], wherein a surface of the thermoelectric conversion member is coated.

According to such a configuration, it is possible to improve strength and abrasion resistance of the thermoelectric conversion member by the coating. Further, by the coating, it is possible to suppress deterioration of the thermoelectric conversion member by oxygen and moisture.

The present invention [6] includes a sensor module including a heat insulating material having a predetermined thickness; a first thermoelectric conversion member having a portion disposed inside the heat insulating material, and having a predetermined length in a thickness direction of the heat insulating material, and generating electromotive force due to a temperature difference in the thickness direction of the heat insulating material; a conversion circuit converting the electromotive force of the first thermoelectric conversion member into a signal; and a control device capable of recording a signal based on the electromotive force of the first thermoelectric conversion member converted by the conversion circuit.

According to such a configuration, the heat insulating material having the predetermined thickness, and the first thermoelectric conversion member are provided.

It is possible to ensure the temperature difference in the thickness direction of the heat insulating material by the heat insulating material.

The first thermoelectric conversion member has the portion disposed inside the heat insulating material. The portion disposed inside the heat insulating material has the predetermined length in the thickness direction.

Therefore, the first thermoelectric conversion member can generate the large electromotive force by utilizing the temperature difference ensured by the heat insulating material.

Then, the sensor module converts the electromotive force of the first thermoelectric conversion member into the signal by the conversion circuit, and is capable of recording the signal in the control device.

Therefore, it is possible to install the sensor module in the place where the power source is difficult to be ensured.

The present invention [7] includes the sensor module of the above-described [6] further including a second thermoelectric conversion member being independent from the first thermoelectric conversion member; having the portion disposed inside the heat insulating material, and having the predetermined length in the thickness direction of the heat insulating material; and generating the electromotive force due to the temperature difference in the thickness direction of the heat insulating material, wherein at least one of the conversion circuit and the control device operates by the electromotive force of the second thermoelectric conversion member.

According to such a configuration, it is possible to operate the sensor module with the second thermoelectric conversion member as the power source in the place where the power source is difficult to be ensured.

The present invention [8] includes a sensor module including a heat insulating material having a predetermined thickness; a first thermoelectric conversion member having a portion disposed inside the heat insulating material, and having a predetermined length in a thickness direction of the heat insulating material, and generating electromotive force due to a temperature difference in the thickness direction of the heat insulating material; a conversion circuit converting the electromotive force of the first thermoelectric conversion member into a signal; and a transmission module capable of transmitting the signal based on the electromotive force of the first thermoelectric conversion member converted by the conversion circuit.

According to such a configuration, the heat insulating material having the predetermined thickness, and the first thermoelectric conversion member are provided.

It is possible to ensure the temperature difference in the thickness direction of the heat insulating material by the heat insulating material.

The first thermoelectric conversion member has the portion disposed inside the heat insulating material. The portion disposed inside the heat insulating material has the predetermined length in the thickness direction.

Therefore, the first thermoelectric conversion member can generate the large electromotive force by utilizing the temperature difference ensured by the heat insulating material.

Then, the sensor module converts the electromotive force of the first thermoelectric conversion member into the signal by the conversion circuit, and is capable of transmitting the signal by the transmission module.

Therefore, it is possible to install the sensor module in the place where the power source is difficult to be ensured.

The present invention [9] includes the sensor module of the above-described [8] including a control device capable of controlling the transmission module.

The present invention [10] includes the sensor module of the above-described [9], wherein the control device is capable of recording the signal based on the electromotive force of the first thermoelectric conversion member converted by the conversion circuit.

The present invention [11] includes the sensor module of any one of the above-described [8] to [10] including a wireless module as the transmission module.

The present invention [12] includes the sensor module of any one of the above-described [8] to [11] further including a second thermoelectric conversion member being independent from the first thermoelectric conversion member; having the portion disposed inside the heat insulating material, and having the predetermined length in the thickness direction of the heat insulating material; and generating the electromotive force due to the temperature difference in the thickness direction of the heat insulating material, wherein at least one of the conversion circuit and the transmission module operates by the electromotive force of the second thermoelectric conversion member.

According to such a configuration, it is possible to operate the sensor module with the second thermoelectric conversion member as the power source in the place where the power source is difficult to be ensured.

The present invention [13] includes the sensor module of any one of the above-described [6] to [12] having the plurality of first thermoelectric conversion members being independent from each other, wherein the conversion circuit is capable of converting the electromotive force of the plurality of first thermoelectric conversion members into signals.

According to such a configuration, it is possible to carry out sensing of the plurality of sites.

The present invention [14] includes the sensor module of any one of the above-described [6] to [13], wherein the heat insulating material is a heat insulating material for piping.

### Effect of the Invention

According to the thermoelectric conversion element of the present invention, it is available as the sensor or the power source in the place where the power source is difficult to be ensured.

Also, according to the sensor module of the present invention, it is possible to be installed in the place where the power source is difficult to be ensured.

### BRIEF DESCRIPTION OF THE DRAWINGS

FIG. 1 shows a cross-sectional view of one embodiment of a thermoelectric conversion element of the present invention.

FIG. 2 shows a perspective view for illustrating a first modified example of a thermoelectric conversion element.

FIG. 3 shows a cross-sectional view for illustrating a second modified example of a thermoelectric conversion element.

FIG. 4 shows a cross-sectional view for illustrating a third modified example of a thermoelectric conversion element.

FIG. 5 shows a perspective view of one embodiment of a sensor module of the present invention.

FIG. 6 shows a cross-sectional view for illustrating a state where the sensor module shown in FIG. 5 is installed around piping.

FIG. 7 shows a block view of the sensor module shown in FIG. 5.

### DESCRIPTION OF EMBODIMENTS

### 1. Thermoelectric Conversion Element

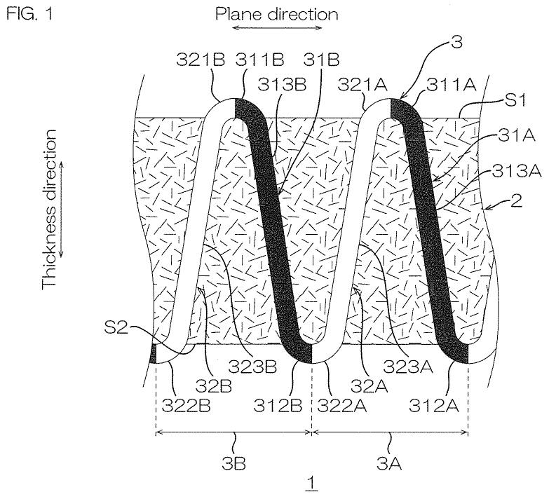

One embodiment of a thermoelectric conversion element 1 is described as reference to FIG. 1.

The thermoelectric conversion element 1 is an element for converting a temperature difference into electricity. The thermoelectric conversion element 1 is a π-type thermoelectric conversion element. The thermoelectric conversion element 1 includes a heat insulating material 2 and a thermoelectric conversion member 3. In this embodiment, the thermoelectric conversion element 1 consists of only the heat insulating material 2 and the thermoelectric conversion member 3.

### (1) Heat Insulating Material

The heat insulating material 2 has a predetermined thickness. The heat insulating material 2 has one surface S1 and another surface S2 in a thickness direction of the heat insulating material 2. In the following description, the thickness direction of the heat insulating material 2 is described as the “thickness direction”. The one surface S1 and the other surface S2 extend in a plane direction. The plane direction intersects the thickness direction. Preferably, the plane direction is perpendicular to the thickness direction.

The heat insulating material 2 has heat insulation properties and insulation properties. The heat insulation properties of the heat insulating material 2 can be defined by thermal conductivity of the heat insulating material 2. The insulation properties of the heat insulating material 2 can be defined by a resistance value of the heat insulating material 2.

The thermal conductivity of the heat insulating material 2 is, for example, 1 W/m K or less, preferably 0.5 W/m K or less. When the thermal conductivity of the heat insulating material 2 is the above-described upper limit value or less, it is possible to ensure a temperature difference in the thickness direction, and it is possible to increase electromotive force to be obtained.

The lower limit value of the thermal conductivity of the heat insulating material 2 is not limited. The thermal conductivity of the heat insulating material 2 is, for example, 0.01 W/m K or more.

The resistance value of the heat insulating material 2 is not limited, as long as a short circuit of the thermoelectric conversion member 3 can be prevented.

Examples of a material for the heat insulating material 2 include glass wool, rock wool, calcium silicate, polystyrene, polyethylene, urethane resins, melamine resins, phenolic resins, foamed glass, pearlite, cellulose fiber, alumina fiber, ceramic fiber, carbon fiber, fumed silica, and alkali earth silicate. As the material for the heat insulating material 2, preferably, glass wool, rock wool, and calcium silicate are used, more preferably, glass wool is used.

The heat insulating material 2 may consist of only one kind of material for the heat insulating material 2 described above. The heat insulating material 2 may include two or more kinds of materials for the heat insulating material 2 described above. The heat insulating material 2 includes at least one of glass wool, rock wool, and calcium silicate. When the heat insulating material 2 includes at least one of glass wool, rock wool, and calcium silicate, it is possible to improve the heat insulation properties of the heat insulating material 2. Thus, it is possible to ensure the temperature difference in the thickness direction, and it is possible to increase the electromotive force to be obtained. Preferably, the heat insulating material 2 includes a layer made of at least one of glass wool, rock wool, and calcium silicate. More preferably, the heat insulating material 2 is made of glass wool.

A thickness of the heat insulating material 2 is, for example, 10 mm or more, preferably 30 mm or more. When the thickness of the heat insulating material 2 is the above-described lower limit value or more, it is possible to ensure the temperature difference in the thickness direction, and it is possible to increase the electromotive force to be obtained.

The upper limit value of the thickness of the heat insulating material 2 is not limited. The thickness of the heat insulating material 2 is, for example, 300 mm or less.

When the heat insulating material 2 is made of the glass wool or the rock wool, apparent density of the heat insulating material 2 is, for example, 200 kg/m³ or less, preferably 100 kg/m³ or less. When the apparent density of the heat insulating material 2 is the above-described upper limit value or less, it is possible to achieve a reduction in weight of the thermoelectric conversion element 1. Further, it is possible to ensure flexibility in a step of sewing the thermoelectric conversion member 3 into the heat insulating material 2.

When the heat insulating material 2 is made of the glass wool or the rock wool, the apparent density of the heat insulating material 2 is, for example, 10 kg/m³ or more, preferably 24 kg/m³ or more. When the apparent density of the heat insulating material 2 is the above-described lower limit value or more, it is possible to ensure the sufficient temperature difference in the thickness direction. Further, it is possible to ensure strength of the heat insulating material 2 to such an extent that the heat insulating material 2 endures the step of sewing the thermoelectric conversion member 3 into the heat insulating material 2.

When the heat insulating material 2 is made of the calcium silicate, the apparent density of the heat insulating material 2 is, for example, 300 kg/m³ or more, preferably 150 kg/m³ or more. When the apparent density of the heat insulating material 2 is the above-described lower limit value or more, it is possible to achieve the reduction in weight of the thermoelectric conversion element 1. Further, it is possible to ensure the flexibility in the step of sewing the thermoelectric conversion member 3 into the heat insulating material 2.

When the heat insulating material 2 is made of the calcium silicate, the apparent density of the heat insulating material 2 is not limited. When the heat insulating material 2 is made of the calcium silicate, the apparent density of the heat insulating material 2 is, for example, 50 kg/m³ or more. When the apparent density of the heat insulating material 2 is the above-described lower limit value or more, it is possible to ensure the sufficient temperature difference in the thickness direction. Further, it is possible to ensure the strength of the heat insulating material 2.

### (2) Thermoelectric Conversion Member

The thermoelectric conversion member 3 generates the electromotive force due to the temperature difference in the thickness direction. The thermoelectric conversion member 3 has a plurality of P-type portions 31A and 31B and a plurality of N-type portions 32A and 32B.

The P-type portion 31A operates as a P-type semiconductor. The P-type portion 31A extends in the thickness direction. In this embodiment, the P-type portion 31A passes through the heat insulating material 2. The P-type portion 31A has a one end portion 311A, another end portion 312A, and a main body portion 313A. The one end portion 311A is disposed outside the heat insulating material 2. The one end portion 311A is disposed on the one surface S1 of the heat insulating material 2. The other end portion 312A is disposed outside the heat insulating material 2. The other end portion 312A is disposed on the other surface S2 of the heat insulating material 2. The main body portion 313A is disposed between the one end portion 311A and the other end portion 312A. The main body portion 313A is disposed inside the heat insulating material 2. That is, the thermoelectric conversion member 3 has a portion disposed inside the heat insulating material 2 (the main body portion 313A). The main body portion 313A has the same length as the thickness of the heat insulating material 2 in the thickness direction. That is, the main body portion 313A has a predetermined length in the thickness direction. The main body portion 313A may not extend along the thickness direction. The main body portion 313A may be inclined with respect to the thickness direction.

The N-type portion 32A operates as an N-type semiconductor. The N-type portion 32A extends in the thickness direction. In this embodiment, the N-type portion 32A passes through the heat insulating material 2. The N-type portion 32A has a one end portion 321A, another end portion 322A, and a main body portion 323A. The one end portion 321A is disposed outside the heat insulating material 2. The one end portion 321Ais disposed on the one surface S1 of the heat insulating material 2. The other end portion 322A is disposed outside the heat insulating material 2. The other end portion 322A is disposed on the other surface S2 of the heat insulating material 2. The main body portion 323A is disposed between the one end portion 321A and the other end portion 322A. The main body portion 323A is disposed inside the heat insulating material 2. The main body portion 323A has the same length as the thickness of the heat insulating material 2 in the thickness direction.

Then, the one end portion 321A of the N-type portion 32A is electrically connected to the one end portion 311A of the P-type portion 31A. Thus, one cell structure 3A of the π-type thermoelectric conversion element is formed from the P-type portion 31A and the N-type portion 32A.

Further, one cell structure 3B of the π-type thermoelectric conversion element is formed from the P-type portion 31B and the N-type portion 32B in the same manner as the P-type portion 31A and the N-type portion 32A.

Then, the other end portion 322A of the N-type portion 32A is electrically connected to the other end portion 312B of the P-type portion 31B. Thus, the cell structure 3A and the cell structure 3B are connected in series.

In this embodiment, the thermoelectric conversion member 3 has a thread-shape in which the P-type portion 31 and the N-type portion 32 are disposed alternately. The thermoelectric conversion member 3 is sewn into the heat insulating material 2 so that a connecting portion between the P-type portion 31 and the N-type portion 32 is disposed on the surface of the heat insulating material 2.

A diameter of the thermoelectric conversion member 3 is, for example, 150 m or more, preferably 300 m or more. When the diameter of the thermoelectric conversion member 3 is the above-described lower limit value or more, it is possible to increase the electromotive force of the thermoelectric conversion member 3.

The “diameter of the thermoelectric conversion member 3” is the minimum length of the thermoelectric conversion member 3 in a direction perpendicular to the direction in which the thermoelectric conversion member 3 extends (radial direction of the thermoelectric conversion member 3). Specifically, when a cross section of the thermoelectric conversion member 3 in the radial direction is circular, the “diameter of the thermoelectric conversion member 3” refers to the diameter of the circle. When the cross section of the thermoelectric conversion member 3 in the radial direction is elliptical, the “diameter of the thermoelectric conversion member 3” refers to the length of the short axis of the ellipse. When the thermoelectric conversion member 3 is in a ribbon shape, the “diameter of the thermoelectric conversion member 3” refers to the thickness of the thermoelectric conversion member 3.

The diameter of the thermoelectric conversion member 3 is, for example, 3000 m or less, preferably 1500 m or less, more preferably 1000 m or less. When the diameter of the thermoelectric conversion member 3 is the above-described upper limit value or less, it is possible to suppress the reduction in the heat insulation properties of the heat insulating material 2 by the thermoelectric conversion member 3 sewn into the heat insulating material 2.

Tensile strength of the thermoelectric conversion member 3 is, for example, 200 mN or more, preferably 400 mN or more. When the tensile strength of the thermoelectric conversion member 3 is the above-described lower limit value or more, it is possible to suppress rupture of the thermoelectric conversion member 3 in the step of sewing the thermoelectric conversion member 3 into the heat insulating material 2.

The tensile strength of the thermoelectric conversion member 3 is measured by a method described in Examples to be described later.

The upper limit value of the tensile strength of the thermoelectric conversion member 3 is not limited. The tensile strength of the thermoelectric conversion member 3 is, for example, 3000 mN or less.

The thermoelectric conversion member 3 includes an electrically conductive material, a binder and, if necessary, a dopant.

The electrically conductive material has electrical conductivity. The electrically conductive material imparts the electrical conductivity to the thermoelectric conversion member 3. Examples of the electrically conductive material include semiconductor materials, carbon materials, and electrically conductive polymers.

Examples of the semiconductor material include bismuth (Bi), tellurium (Te), antimony (Sb), cobalt (Co), zinc (Zn), silicon (Si), germanium (Ge), iridium (Ir), lead (Pb), alloys of these, skutterudite, and constantan. The semiconductor material may contain a metal element, and may have the higher resistance value than the metal and may function as a semiconductor by a crystal structure or a combination of elements in the alloy. The semiconductor material may be a semiconductor whisker.

Examples of the carbon material include carbon nanotube, carbon nanofiber, graphene, graphene nanoribbon, and fullerene nanowhisker.

Examples of the electrically conductive polymer include polyacetylene, poly(p-phenylene vinylene), polypyrrole, polythiophene, polyaniline, poly(p-phenylene sulfide), composite of poly(3,4-ethylenedioxythiophene) and polystyrenesulfonic acid (PEDOT: PSS), composite of poly(3,4-ethylenedioxythiophene) and polypropylsulfonic acid methylsiloxane (PEDOT: PSiPS), and composite of poly(3,4-ethylenedioxythiophene) and paratoluenesulfonic acid (PEDOT: Tos).

As the electrically conductive material, preferably, a carbon material is used, more preferably, a carbon nanotube is used. That is, the thermoelectric conversion member 3 preferably includes the carbon nanotube, the binder, and, if necessary, the dopant. When the electrically conductive material is the carbon nanotube, it is possible to efficiently produce the thermoelectric conversion member 3 by utilizing electrical properties as the P-type semiconductor of the carbon nanotube.

A ratio of the electrically conductive material in the thermoelectric conversion member 3 is, for example, 30% by mass or more, preferably 40% by mass or more, more preferably 50% by mass or more. When the ratio of the electrically conductive material is the above-described lower limit value or more, it is possible to ensure the electrical conductivity of the thermoelectric conversion member 3.

The ratio of the electrically conductive material in the thermoelectric conversion member 3 is, for example, 70% by mass or less, preferably 60% by mass or less. When the ratio of the electrically conductive material is the above-described upper limit value or less, it is possible to ensure the ratio of the binder, and to ensure the tensile strength of the thermoelectric conversion member 3.

The ratio of the electrically conductive material in the thermoelectric conversion member 3 is, for example, 40 parts by mass or more, preferably 60 parts by mass or more with respect to 100 parts by mass of the binder. When the ratio of the electrically conductive material is the above-described lower limit value or more, it is possible to ensure the electrical conductivity of the thermoelectric conversion member 3.

The ratio of the electrically conductive material in the thermoelectric conversion member 3 is, for example, 250 parts by mass or less, preferably 150 parts by mass or less with respect to 100 parts by mass of the binder. When the ratio of the electrically conductive material is the above-described upper limit value or less, it is possible to ensure the ratio of the binder, and to ensure the tensile strength of the thermoelectric conversion member 3.

The binder binds an electrically conductive substance. When the electrically conductive substance is the carbon nanotube, the binder binds the carbon nanotube. Examples of the binder include insulating resins and electrically conductive resins.

Examples of the insulating resin include polyethylene glycol, epoxy resins, acrylic resins, urethane resins, polystyrene resins, and polyvinyl resins. Examples of the polyvinyl resin include polyvinyl chloride, polyvinyl pyrrolidone, polyvinyl alcohol, and polyvinyl acetate.

Examples of the electrically conductive resin include polyacetylene, poly(p-phenylenevinylene), polypyrrole, polythiophene, polyaniline, poly(p-phenylene sulfide), and poly(3,4-ethylenedioxythiophene).

As the binder, preferably, an insulating resin is used, more preferably, polyethylene glycol is used.

The ratio of the binder in the thermoelectric conversion member 3 is, for example, 30% by mass or more, preferably 40% by mass or more. When the ratio of the binder is the above-described lower limit value or more, it is possible to ensure the tensile strength of the thermoelectric conversion member 3.

The ratio of the binder in the thermoelectric conversion member 3 is, for example, 70% by mass or less, preferably 60% by mass or less. When the ratio of the binder is the above-described upper limit value or less, it is possible to ensure the ratio of the electrically conductive material, and to ensure the electrical conductivity of the thermoelectric conversion member 3.

The ratio of the binder in the thermoelectric conversion member 3 is, for example, 40 parts by mass or more, preferably 60 parts by mass or more with respect to 100 parts by mass of the electrically conductive material. When the ratio of the binder is the above-described lower limit value or more, it is possible to ensure the tensile strength of the thermoelectric conversion member 3.

The ratio of the binder in the thermoelectric conversion member 3 is, for example, 250 parts by mass or less, preferably 150 parts by mass or less with respect to 100 parts by mass of the electrically conductive resin. When the ratio of the binder is the above-described upper limit value or less, it is possible to ensure the ratio of the electrically conductive material, and to ensure the electrical conductivity of the thermoelectric conversion member 3.

The dopant imparts the electrical properties of the semiconductor to the thermoelectric conversion member 3. Examples of the dopant include P-type dopants and N-type dopants. The P-type dopant imparts the electrical properties of the P-type semiconductor to the thermoelectric conversion member 3. When the electrically conductive substance is the carbon nanotube, since the carbon nanotube has the electrical properties of the P-type semiconductor, the thermoelectric conversion member 4 may not contain the P-type dopant. The N-type dopant imparts the electrical properties of the N-type semiconductor to the thermoelectric conversion member 3. Examples of the N-type dopant include 1-butyl-3-methylimidazolium hexafluorophosphate (BMIM-PF6), polyethyleneimine (PEI), ethylenediamine tetrakis(propoxylate-block-ethoxylate)tetrol (trade name: Tetronic (registered trade mark) 1107), reduced benzylviologen (reduced BV), diphenylphosphine (dpp), 1,2-bis(diphenylphosphino)ethane (dppe), 1,3-bis(diphenylphosphino)propane (dppp), 1,4-bis(diphenylphosphino)butane (dppb), bis(diphenylphosphinomethyl)phenylphosphine (dpmp), bis(diphenylphosphinoethyl)phenylphosphine (ppmdp), bis[(diphenylphosphinomethyl)phenylphosphino]methane (dpmppm), triphenylphosphine (tpp), tris(p-fluorophenyl)phosphine (F-tpp), tris(p-chlorophenyl)phosphine (CL-tpp), tris(p-methoxyphenyl)phosphine (MeO-tpp), tris(4-methoxy-3,5-dimethylphenyl)phosphine (tmdp), indole (Id), polyvinylpyrrole (PVPy), polyvinylpyrrolidone (PVP), 1,3-dimethyl-2-(o-methoxyphenyl)benzoimidazole (o-MeO-DMBI), hydrazine hydrate (HH), phenylhydrazine (MPH), and 1,2-diphenylhydrazine (DPH). As the N-type dopant, preferably, triphenylphosphine is used.

The surface of the thermoelectric conversion member 3 may be coated. In other words, the thermoelectric conversion member 3 may also have a core portion containing the electrically conductive material, the binder, and the dopant, and a coating layer coating the surface of the core portion. Examples of the material for the coating layer include resins, carbon fibers, metals, metal oxide, and silicon compounds. Examples of the resin include epoxy resins, acrylic resins, urethane resins, fluororesins, polyvinyl alcohol, ethylene vinyl alcohol, polybutylene terephthalate, polyamide, polyimide, polyvinyl acetal, polysilsesquioxane, polysilazane, and parylene. Examples of the carbon fiber include carbon nanofibers. Examples of the metal include aluminum and chromium. Examples of the metal oxide include smectite, indium tin oxide (ITO), indium zinc oxide (IZO), aluminum zinc oxide (AZO), and zinc tin oxide (ZTO). Examples of the silicon compound include silica microparticles, silicon dioxide, and silicon nitride. It is possible to improve the strength and abrasion resistance of the thermoelectric conversion member 3 by the coating layer. Further, by the coating layer, it is possible to suppress deterioration of the thermoelectric conversion member 3 by oxygen and moisture.

### (3) Method for Producing Thermoelectric Conversion Element

In order to produce the thermoelectric conversion element 1, first, the thermoelectric conversion member 3 is produced.

In order to produce the thermoelectric conversion member 3, first, a mixture of the electrically conductive material and the binder is molded into the thread-shape.

Next, the dopant is imparted to the obtained molded article. In order to impart the dopant, for example, the molded article is immersed in a solution containing the dopant. When the electrically conductive material is the carbon nanotube, the N-type dopant is imparted to a portion of the mold article to be desired to be an N-type portion 32.

Thus, in the molded article, the portion imparted with the N-type dopant becomes the N-type portion 32, and the portion not imparted with the N-type dopant becomes a P-type portion 31 due to the electrical properties of the carbon nanotube. The P-type dopant may be also imparted to the portion of the molded article to be desired to be the P-type portion 31.

Thus, the thermoelectric conversion member 3 is obtained.

In a method for molding the mixture of the electrically conductive material and the binder into the thread-shape, it is possible to increase the ratio of the electrically conductive material per weight of the thermoelectric conversion member 3. Therefore, it is possible to produce the thermoelectric conversion member 3 capable of obtaining the large electromotive force.

The thermoelectric conversion member 3 may be also produced by a method other than the method of molding the mixture of the electrically conductive material and the binder into the thread-shape. For example, the thermoelectric conversion member 3 may be also produced by carrying or immersing the electrically conductive material into a plant fiber or a synthetic fiber, and adding the dopant or the binder as needed. Examples of the plant fiber include cotton, hemp, and pulp. Examples of the synthetic fiber include polypropylene and polyethylene.

Next, in order to produce the thermoelectric conversion element 1, the obtained thermoelectric conversion member 3 is sewn into the heat insulating material 2 so that the connecting portion between the P-type portion 31 and the N-type portion 32 is disposed on the surface of the heat insulating material 2.

Thus, the thermoelectric conversion element 1 is obtained

### 2. Function and Effect of Thermoelectric Conversion Element

According to the thermoelectric conversion element 1, as shown in FIG. 1, the heat insulating material 2 having the predetermined thickness and the thermoelectric conversion member 3 are provided.

It is possible to ensure the temperature difference in the thickness direction of the heat insulating material 2 by the heat insulating material 2.

The thermoelectric conversion member 3 has the portions (the main body portions 313A, 313B, 323A, and 323B) disposed inside the heat insulating material 2. The main body portions 313A, 313B, 323A, and 323B of the thermoelectric conversion member 3 have the predetermined length in the thickness direction.

Therefore, the thermoelectric conversion member 3 can generate the large electromotive force by utilizing the temperature difference ensured by the heat insulating material 2. In particular, since the diameter of the thermoelectric conversion member 3 is 150 m or more, it is possible to increase the electromotive force.

As a result, the thermoelectric conversion element 1 is available as a sensor or a power source in a place where the power source is difficult to be ensured.

### 3. Modified Examples of Thermoelectric Conversion Element

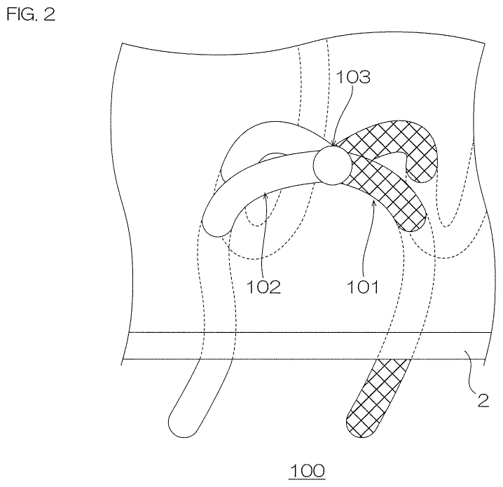

Hereinafter, modified examples of the thermoelectric conversion element 1 are described with reference to FIGS. 2 to 4. In the description of the modified example, the same reference numerals are provided for members corresponding to each of those in the above-described embodiment, and their detailed description is omitted.

(1) As shown in FIG. 2, a thermoelectric conversion element 100 may also have a P-type thermoelectric conversion member 101 consisting of only the P-type portion 31 and an N-type thermoelectric conversion member 102 consisting of only the N-type portion 32 instead of the thermoelectric conversion member 3 having the P-type portion 31 and the N-type portion 32. Then, one end portion of the P-type thermoelectric conversion member 101 in the thickness direction and one end portion of the N-type thermoelectric conversion member 102 in the thickness direction may be also electrically connected by an electrically conductive paste 103 or the like.

In this case, each of the P-type thermoelectric conversion member 101 and the N-type thermoelectric conversion member 102 is the thread-shape, and may be sewn into the heat insulating material 2.

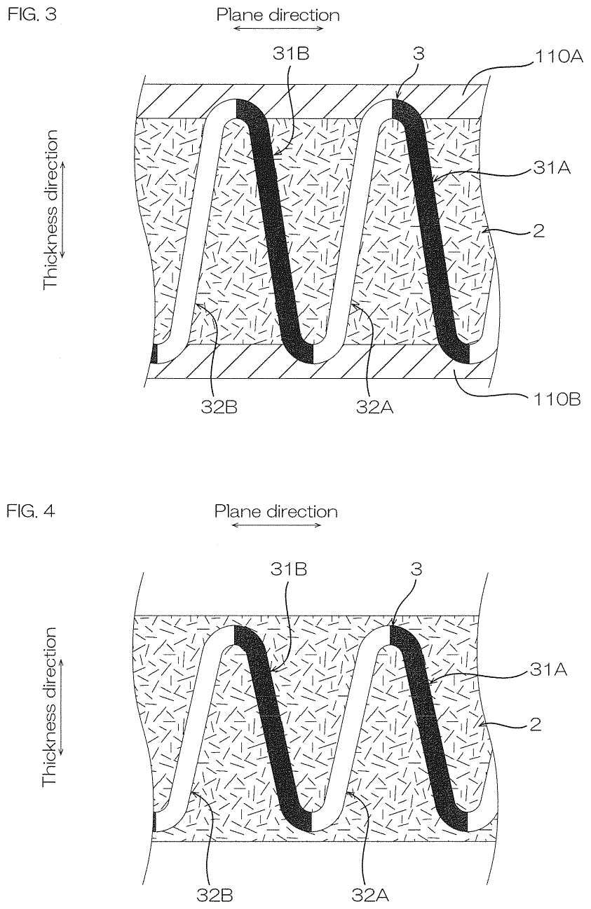

(2) As shown in FIG. 3, the thermoelectric conversion element 1 may also have cover layers 110A and 110B which cover the connecting portion between the P-type portion 31 and the N-type portion 32. The thermoelectric conversion element 1 may also consist of only the heat insulating material 2, the thermoelectric conversion member 3, and the cover layers 110A and 110B. As the material for the cover layers 110A and 110B, for example, the above-described material for the heat insulating material 2 is used. The cover layers 110A and 110B may also have a coating layer. As the material for the coating layer, for example, the above-described material for the coating layer of the thermoelectric conversion member 3 is used.

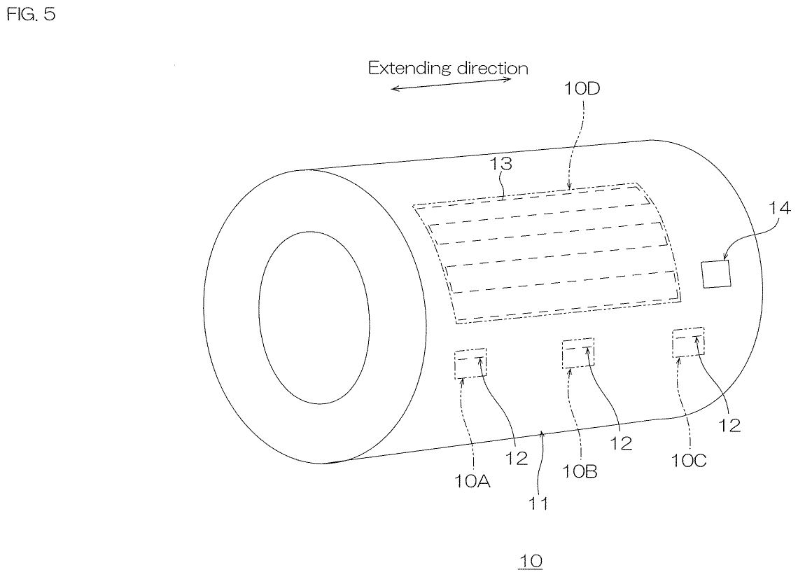

Further, as shown in FIG. 4, the entire thermoelectric conversion member 3 may be also disposed inside the heat insulating material 2. In other words, the thermoelectric conversion member 3 may also consist of only the portion disposed inside the heat insulating material 2.

(3) In the above-described modified example, the same function and effect as that of the embodiment can be also obtained.

### 4. Sensor Module

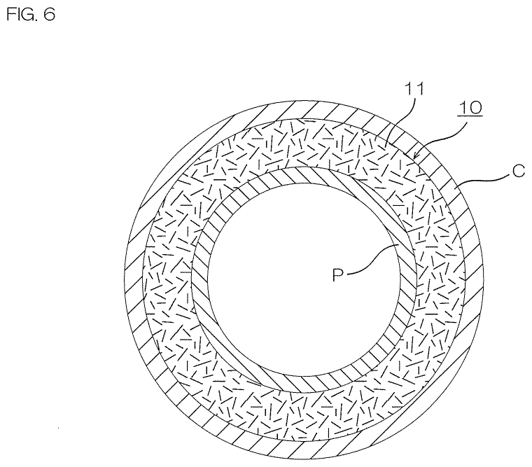

Next, one embodiment of a sensor module 10 is described with reference to FIGS. 5 to 7.

As shown in FIG. 5, the sensor module 10 includes a heat insulating material 11, a plurality of first thermoelectric conversion members 12, one second thermoelectric conversion member 13, and a circuit board 14. The sensor module 10 may include at least one first thermoelectric conversion member 12. Further, the sensor module 10 may also include the plurality of second thermoelectric conversion members 13.

### (1) Heat Insulating Material

As shown in FIGS. 5 and 6, the heat insulating material 11 is the heat insulating material for piping P. The heat insulating material 11 covers the outer peripheral surface of the piping P. In this embodiment, the heat insulating material 11 has a cylindrical shape. The heat insulating material 11 extends in a direction in which the piping P extends. In the following description, the direction in which the piping P extends is described as an extending direction. A shape of the heat insulating material 11 is not limited, as long as it can cover the piping P. For example, the heat insulating material 11 may also have a flat plate shape. For example, when the heat insulating material 11 has the flat plate shape, the heat insulating material 11 may be also curved along the outer peripheral surface of the piping P. The heat insulating material 11 is covered by a cover C. The piping P and the cover C are made of metal.

When the heat insulating material 11 is a heat insulating material for the piping P, as the material for the heat insulating material 11, preferably, glass wool, rock wool, and calcium silicate are used. The heat insulating material 11 includes at least one of glass wool, rock wool, and calcium silicate. Preferably, the heat insulating material 11 includes a layer made of at least one of glass wool, rock wool, and calcium silicate. When the heat insulating material 11 contains at least one of glass wool, rock wool, and calcium silicate, the heat insulating material 11 is preferable as the heat insulating material for the piping P.

When the heat insulating material 11 is the heat insulating material for the piping P, the thermal conductivity of the heat insulating material 11 is, for example, 1 W/m K or less, preferably 0.5 W/m K or less. When the thermal conductivity of the heat insulating material 11 is the above-described upper limit value or less, the heat insulating material 11 is preferable as the heat insulating material for the piping P.

The lower limit value of the thermal conductivity of the heat insulating material 11 is not limited. The thermal conductivity of the heat insulating material 11 is, for example, 0.01 W/m K or more.

### (2) First Thermoelectric Conversion Member

Each of the plurality of first thermoelectric conversion members 12 is used as the sensor for detecting an abnormality of the heat insulating material 11.

For example, when the heat insulating material 11 becomes wet, the more the heat insulating material 11 contains moisture, the lower the heat insulation properties of the heat insulating material 11. Therefore, the more the heat insulating material 11 contains moisture, the smaller the temperature difference in the thickness direction of the heat insulating material 11. Then, the electromotive force of the first thermoelectric conversion member 12 is reduced. Therefore, by detecting the reduction in the electromotive force of the first thermoelectric conversion member 12, it is possible to detect wetting of the heat insulating material 11 (abnormality of the heat insulating material 11).

Each of the plurality of first thermoelectric conversion members 12 is sewn into the heat insulating material 11. Each of the plurality of first thermoelectric conversion members 12 has the same structure and component as the thermoelectric conversion member 3 of the thermoelectric conversion element 1 described above. Therefore, descriptions of the structure and the component of each of the plurality of first thermoelectric conversion members 12 are omitted. Each of the plurality of first thermoelectric conversion members 12 generates the electromotive force due to the temperature difference in the thickness direction of the heat insulating material 11. Each of the plurality of first thermoelectric conversion members 12 has the portion (main body portion) disposed inside the heat insulating material 11. The main body portion of the first thermoelectric conversion member 12 has the predetermined length in the thickness direction of the heat insulating material 11.

In the sensor module 10, portions 10A, 10B, and 10C in which the first thermoelectric conversion member 12 is sewn into the heat insulating material 11 have the same structure as the above-described thermoelectric conversion element 1. That is, the sensor module 10 has the plurality of thermoelectric conversion elements 1 as the sensor.

The plurality of first thermoelectric conversion members 12 are independent from each other. The plurality of first thermoelectric conversion members 12 are spaced apart from each other in the extending direction.

### (3) Second Thermoelectric Conversion Member

The second thermoelectric conversion member 13 is used as the power source for the circuit board 14.

The second thermoelectric conversion member 13 is sewn into the heat insulating material 11. Each of the second thermoelectric conversion members 13 has the same structure and component as the thermoelectric conversion member 3 of the thermoelectric conversion element 1 described above. Therefore, the descriptions of the structures and the components of the second thermoelectric conversion member 13 are omitted. The second thermoelectric conversion member 13 generates the electromotive force due to the temperature difference in the thickness direction of the heat insulating material 11. The second thermoelectric conversion member 13 has the portion (main body portion) disposed inside the heat insulating material 11. The main body portion of the second thermoelectric conversion member 13 has the predetermined length in the thickness direction of the heat insulating material 11.

In the sensor module 10, a portion 10D in which the second thermoelectric conversion member 13 is sewn into the heat insulating material 11 has the same structure as the above-described thermoelectric conversion element 1. That is, the sensor module 10 has the thermoelectric conversion element 1 as the power source.

The second thermoelectric conversion member 13 is independent from the plurality of first thermoelectric conversion members 12. The second thermoelectric conversion member 13 extends in the extending direction, and also extends in a circumferential direction of the heat insulating material 11, while being folded back.

### (4) Circuit Board

The circuit board 14 is installed on the surface of the heat insulating material 11. The circuit board 14 may be embedded in the heat insulating material 11, or may be installed on the cover C covering the heat insulating material 11 (ref. FIG. 6).

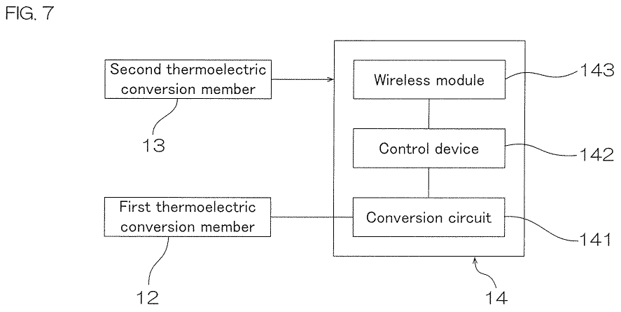

As shown in FIG. 7, the circuit board 14 includes a conversion circuit 141, a control device 142, and a wireless module 143 as a transmission module. In other words, the sensor module 10 includes the conversion circuit 141, the control device 142, and the wireless module 143 as the transmission module. The circuit board 14 is electrically connected to the plurality of first thermoelectric conversion members 12 and the plurality of second thermoelectric conversion members 13. The circuit board 14 operates by the electromotive force of the plurality of second thermoelectric conversion members 13. That is, the conversion circuit 141, the control device 142, and the wireless module 143 operate by the electromotive force of the plurality of second thermoelectric conversion members 13.

### (4-1) Conversion Circuit

The conversion circuit 141 converts the electromotive force of each of the plurality of first thermoelectric conversion members 12 into the signal. Specifically, the conversion circuit 141 converts the electromotive force of each of the plurality of first thermoelectric conversion members 12 into a digital signal. The conversion circuit 141 is electrically connected to each of the plurality of first thermoelectric conversion members 12. The conversion circuit 141 includes an AFE (analog front end) circuit and an analog-digital conversion circuit. The conversion circuit 141 adjusts the electromotive force of each of the plurality of first thermoelectric conversion members 12 by the AFE circuit, and converts it into the digital signal by the analog-digital conversion circuit.

### (4-2) Control Device

The control device 142 is electrically connected to the conversion circuit 141 and the wireless module 143. The control device 142 has a processor and a memory. The control device 142 is capable of recording the signal based on the electromotive force of the first thermoelectric conversion member 12 converted by the conversion circuit 141 in a memory. The control device 142 is capable of controlling the wireless module 143. The control device 142 transmits the signal recorded in the memory to the wireless module 143. The control device 142 may also transmit any signal recorded in the memory to the wireless module 143. When the signal recorded in the memory shows an abnormal value, the control device 142 may transmit the abnormal value to the wireless module 143.

### (4-3) Wireless Module

The wireless module 143 is capable of transmitting the signal based on the electromotive force of the first thermoelectric conversion member 12 controlled by the control device 142, and converted by the conversion circuit 141 (specifically, signal converted by the conversion circuit 141, and recorded in the memory of the control device 142). The communication standard of the wireless module 143 is not limited. The wireless module has at least a transmission antenna.

### 5. Function and Effect of Sensor Module

(1) According to the sensor module 10, as shown in FIG. 4, the heat insulating material 11 having the predetermined thickness and the first thermoelectric conversion member 12 are provided.

It is possible to ensure the temperature difference in the thickness direction of the heat insulating material 11 by the heat insulating material 11.

The first thermoelectric conversion member 12 has the same structure as the thermoelectric conversion member 3 of the thermoelectric conversion element 1 (ref. FIG. 1). That is, the first thermoelectric conversion member 12 has the portion (main body portion) disposed inside the heat insulating material 11, and the main body portion has the predetermined length in the thickness direction.

Therefore, the first thermoelectric conversion member 12 can generate the large electromotive force by utilizing the temperature difference ensured by the heat insulating material 11.

Then, as shown in FIG. 6, the sensor module 10 converts the electromotive force of the first thermoelectric conversion member 12 into the signal by the conversion circuit 141 and can transmit the signal by the wireless module 143.

Therefore, it is possible to install the sensor module 10 in the place where the power source is difficult to be ensured (specifically, inside a heat insulating structure around the piping P; ref: FIG. 5).

Further, when the diameter of the first thermoelectric conversion member 12 is 150 m or more, it is possible to achieve an increase in the electromotive force of the first thermoelectric conversion member 12.

Therefore, even when the temperature difference slightly fluctuates (specifically, is reduced), such as in a case where a small amount of water enters the heat insulating material 11, it is possible to detect the fluctuation (specifically, the reduction) of the electromotive force.

As a result, for example, when the sensor module 10 is installed inside the heat insulating structure around the piping P, it is possible to achieve early discovery of the abnormality in the heat insulating structure leading to corrosion or the like of the piping P.

(2) According to the sensor module 10, as shown in FIG. 4, the plurality of first thermoelectric conversion members 12 which are independent from each other are provided.

Therefore, it is possible to carry out sensing of the plurality of sites.

(3) According to the sensor module 10, as shown in FIG. 4, the second thermoelectric conversion member 13 which is independent from the first thermoelectric conversion member 12 is provided, and the conversion circuit 141, the control device 142, and the wireless module 143 operate by the electromotive force of the second thermoelectric conversion member 13.

Therefore, it is possible to operate the sensor module 10 with the second thermoelectric conversion member 13 as the power source in the place where the power source is difficult to be ensured.

### 6. Modified Examples of Sensor Module

Hereinafter, modified examples of the thermoelectric conversion element 1 are described. In the description of the modified examples, the same reference numerals are provided for members corresponding to each of those in the above-described embodiment, and their detailed description is omitted.

(1) The sensor module 10 may not also include the second thermoelectric conversion member 13. In this case, the sensor module 10 may also include the power source for operating the circuit board 14 instead of the second thermoelectric conversion member 13. The power source may be also a Peltier element obtained by connecting a block of a semiconductor by a conductor. The power source may be also a secondary battery. The secondary battery may be also rechargeable by non-contact charging.

(2) The control device 142 may not also control the wireless module 143. In this case, the circuit board 14 has a non-volatile memory, and the control device 142 may also record data in the non-volatile memory. The data recorded in the non-volatile memory may be readable by an external reader through the wireless module 143.

(3) The thermoelectric conversion element 1 may not also include the wireless module 143. In this case, the circuit board 14 has the non-volatile memory, and the control device 142 records the data in the non-volatile memory. The non-volatile memory may be also, for example, a memory card detachable to the control device 142 through a slot provided in the cover C.

(4) The wireless module 143 may be also independent from the circuit board 14.

(5) The applications of the sensor module are not limited to the heat insulating structure of the piping P. Examples of the applications of the sensor module include heat insulating structures of exterior walls of houses, heat insulating structures in engine rooms of automobiles, and interiors of vacuum heat insulating materials.

(6) The above-described modified examples can also obtain the same function and effect as that of the embodiment.

### EXAMPLES

Next, the present invention is further described based on Examples and Comparative Example below. The present invention is however not limited by Examples and Comparative Example. The specific numerical values in number of blended parts, diameter, and property value used in Examples and Comparative Example can be replaced with upper limit values (numerical values defined as “or less”) or lower limit values (numerical values defined as “or more”) of corresponding numerical values in number of blended parts, diameter, and property value described in the above-described “DESCRIPTION OF EMBODIMENTS”.

### 1. Production of Thermoelectric Conversion Element

### Example 1

### (1) Preparation of Thermoelectric Conversion Member

A thermoelectric conversion member corresponding to the thermoelectric conversion member 3 of FIG. 1 was prepared. The material, the length, the diameter, the number of P-type portions, and the number of N-type portions of the thermoelectric conversion member are described below.

### Materials:

Electrically conductive material: 50 parts by mass of carbon nanotube
Binder: 50 parts by mass of polyethylene glycol
N-type dopant: triphenylphosphine
Length of thermoelectric conversion member: 150 mm
Diameter of thermoelectric conversion member: 150 m
Number of P-type portions: 2
Number of N-type portions: 2

### (2) Production of Thermoelectric Conversion Element

By the above-described production method, the thermoelectric conversion element corresponding to the thermoelectric conversion element 1 of FIG. 1 was produced. To be more specific, the thermoelectric conversion element having two π-type cell structures was produced by folding and sewing the thermoelectric conversion member so as to pass through from one surface to the other surface of the heat insulating material (material: glass wool, thickness of 40 mm).

### Examples 2 to 5 and Comparative Example 1

By using the thermoelectric conversion member having the diameter shown in Table 1, the thermoelectric conversion element was produced in the same manner as in Example 1.

### 2. Evaluation of Thermoelectric Conversion Member

### (1) Resistivity

As for each of the thermoelectric conversion members of Examples 1 to 5 and Comparative Example 1, electrical resistance of the thermoelectric conversion member was measured using a digital multimeter, and the electrical resistance (resistivity (Q/cm)) per 1 cm of the thermoelectric conversion member was obtained. The smaller the resistivity, the larger the electro motive force was obtained.

### (2) Tensile Test

Each of the thermoelectric conversion members of Examples 1 to 5 and Comparative Example 1 was cut into a length of 65 mm, thereby forming a sample. The obtained sample was pulled at a rate of 1 mm/i min using a tensile testing machine (manufactured by Shimadzu Corporation, EZ-S), thereby measuring the tensile strength.

The tensile strength of the thermoelectric conversion member was evaluated by the following criteria. The results are shown in Table 1.

∘: The tensile strength was 200 mN or more.

X: The tensile strength was below 200 mN.

### (3) Handleability in Sewing Step

In the step of sewing the thermoelectric conversion member into the heat insulating material (sewing step), handleability was evaluated based on the following criteria. The results are shown in Table 1. When the tensile strength is 200 mN or more, it is found that the excellent handleability in the sewing step is achieved.

∘: The rupture of the thermoelectric conversion member was suppressed, and it was possible to smoothly sew the thermoelectric conversion member into the heat insulating material.

x: The thermoelectric conversion member may be ruptured, and an operation of sewing the thermoelectric conversion member into the heat insulating material was not smooth since a bonding operation of the ruptured thermoelectric conversion member was necessary.

### 3. Evaluation of Thermoelectric Conversion Element

As for each of the thermoelectric conversion elements obtained in Examples 1 to 5 and Comparative Example 1, the electrical resistance was measured. The results are shown in Table 1.

TABLE 1

| | | | | | | | Comparative |
|---|---|---|---|---|---|---|---|
| | | Ex. 1 | Ex. 2 | Ex. 3 | Ex. 4 | Ex. 5 | Ex. 1 |
| Diameter of Thermoelectric | | 150 | 300 | 1000 | 1500 | 3000 | 50 |
| Conversion Member (μm) | | | | | | | |
| Properties of | Resistivity | 16 | 4 | 0.32 | 0.13 | 0.03 | 135 |
| Thermoelectric | (Ω/cm) | | | | | | |
| Conversion Member | Tensile | ◯ | ◯ | ◯ | ◯ | ◯ | X |
| | Strength | | | | | | |

| | | | | | | |
|---|---|---|---|---|---|---|
| Handleability in Sewing Step | ◯ | ◯ | ◯ | ◯ | ◯ | X |
| Electrical Resistance of Thermoelectric | 100 | 25 | 2 | 1 | 0.3 | 922 |
| Conversion Member (Ω) | | | | | | |

While the illustrative embodiments of the present invention are provided in the above description, such is for illustrative purpose only and it is not to be construed as limiting the scope of the present invention. Modification and variation of the present invention that will be obvious to those skilled in the art is to be covered by the following claims.

### INDUSTRIAL APPLICATION

The thermoelectric conversion member and the sensor module of the present invention are, for example, available as a sensor or a power source.

### DESCRIPTION OF REFERENCE NUMERALS

1 Thermoelectric conversion element
2 Heat insulating material
3 Thermoelectric conversion member
Sensor module
11 Heat insulating material
12 First thermoelectric conversion member
13 Second thermoelectric conversion member
141 Conversion circuit
142 Control device
143 Wireless module (transmission module)
100 Thermoelectric conversion element
101 P-type thermoelectric conversion member (one example of thermoelectric conversion member)
102 N-type thermoelectric conversion member (one example of thermoelectric conversion member)
P Piping

1. A thermoelectric conversion element comprising:
a heat insulating material having a predetermined thickness; and
a thermoelectric conversion member having a thread-shape having a diameter of 150 m or more, having a portion disposed inside the heat insulating material and having a predetermined length in a thickness direction of the heat insulating material, and generating electromotive force due to a temperature difference in the thickness direction of the heat insulating material.

2. The thermoelectric conversion element according to claim 1, wherein
the heat insulating material includes at least one of glass wool, rock wool, and calcium silicate.

3. The thermoelectric conversion element according to claim 1, wherein
the thermoelectric conversion member includes a carbon nanotube and a binder binding the carbon nanotube.

4. The thermoelectric conversion element according to claim 3, wherein
the thermoelectric conversion member further includes a dopant.

5. The thermoelectric conversion element according to claim 1, wherein
a surface of the thermoelectric conversion member is coated.

6. A sensor module comprising:
a heat insulating material having a predetermined thickness;
a first thermoelectric conversion member having a portion disposed inside the heat insulating material, and having a predetermined length in a thickness direction of the heat insulating material, and generating electromotive force due to a temperature difference in the thickness direction of the heat insulating material;
a conversion circuit converting the electromotive force of the first thermoelectric conversion member into a signal; and
a control device capable of recording a signal based on the electromotive force of the first thermoelectric conversion member converted by the conversion circuit.

7. The sensor module according to claim 6 further comprising:
a second thermoelectric conversion member being independent from the first thermoelectric conversion member; having the portion disposed inside the heat insulating material, and having the predetermined length in the thickness direction of the heat insulating material; and generating the electromotive force due to the temperature difference in the thickness direction of the heat insulating material, wherein
at least one of the conversion circuit and the control device operates by the electromotive force of the second thermoelectric conversion member.

8. A sensor module comprising:
a heat insulating material having a predetermined thickness;
a first thermoelectric conversion member having a portion disposed inside the heat insulating material, and having a predetermined length in a thickness direction of the heat insulating material, and generating electromotive force due to a temperature difference in the thickness direction of the heat insulating material;
a conversion circuit converting the electromotive force of the first thermoelectric conversion member into a signal; and
a transmission module capable of transmitting the signal based on the electromotive force of the first thermoelectric conversion member converted by the conversion circuit.

9. The sensor module according to claim 8 comprising:
a control device capable of controlling the transmission module.

10. The sensor module according to claim 9, wherein
the control device is capable of recording the signal based on the electromotive force of the first thermoelectric conversion member converted by the conversion circuit.

11. The sensor module according to claim 8 comprising:
a wireless module as the transmission module.

12. The sensor module according to claim 8 further comprising:
a second thermoelectric conversion member being independent from the first thermoelectric conversion member; having the portion disposed inside the heat insulating material, and having the predetermined length in the thickness direction of the heat insulating material; and generating the electromotive force due to the temperature difference in the thickness direction of the heat insulating material, wherein
at least one of the conversion circuit and the transmission module operates by the electromotive force of the second thermoelectric conversion member.

13. The sensor module according to claim 6 having
the plurality of first thermoelectric conversion members being independent from each other, wherein
the conversion circuit is capable of converting the electromotive force of the plurality of first thermoelectric conversion members into signals.

14. The sensor module according to claim 6, wherein
the heat insulating material is a heat insulating material for piping.

15. The sensor module according to claim 8 having
the plurality of first thermoelectric conversion members being independent from each other, wherein
the conversion circuit is capable of converting the electromotive force of the plurality of first thermoelectric conversion members into signals.

16. The sensor module according to claim 8, wherein
the heat insulating material is a heat insulating material for piping.
